(19) United States
(12) Patent Application Publication
(10) Pub. No.: US 2026/0299412 A1
(43) Pub. Date: Oct. 1, 2026

(54) PHOTOSENSITIVE RESIN COMPOSITION, CURED PRODUCT, AND SEMICONDUCTOR ELEMENT

(71) Applicant: Resonac Corporation, Tokyo (JP)

(72) Inventors: Manabu HIRASAWA, Tokyo (JP); Guillermo FERNANDEZ ZAPICO, Tokyo (JP); Fumihiko KAWAUCHI, Tokyo (JP); Tatsuya MAKINO, Tokyo (JP)

(21) Appl. No.: 19/480,205

(22) PCT Filed: Dec. 11, 2024
(86) PCT No.: PCT/JP2024/043865

§ 371 Date: Oct. 30, 2025

(30) Foreign Application Priority Data
Dec. 18, 2023 (JP) 2023-213172

(51) Int. Cl. G03F 7/027; G03F 7/004; H10W 70/695

(52) U.S. Cl. CPC G03F 7/027; G03F 7/0045; H10W 70/695

(57) ABSTRACT

A photosensitive resin composition according to the present disclosure contains a maleimide compound, a crosslinking agent, a photopolymerization initiator, and a rust inhibitor, in which the maleimide compound is a reaction product of a tetracarboxylic dianhydride (a1), an amine (a2), and a maleic anhydride (a3), and the rust inhibitor contains a compound represented by the following Formula (I),

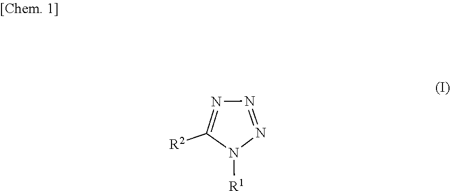

[in Formula (I), X represents a carbon atom or a nitrogen atom, and R¹ and R² each independently represent a hydrogen atom, an alkyl group, an aryl group, or a nitrogen-containing group, where in a case where X represents a nitrogen atom, R¹ and R² do not both represent a hydrogen atom].

### TECHNICAL FIELD

The present disclosure relates to a photosensitive resin composition, a cured product, and a semiconductor element.

### BACKGROUND ART

In accordance with high integration, miniaturization, and

micronization of semiconductor elements, insulating films used for surface protective layers, interlayer insulating layers, redistribution layers, and the like of the semiconductor elements are required to have more excellent electrical characteristics, heat resistance, mechanical characteristics, and the like. Photosensitive resin compositions for forming insulating films having such combined characteristics have been developed (see, for example, Patent Literatures 1, 2, and 3). These photosensitive resin compositions are applied onto a substrate and dried to form a resin film, and the resin film is exposed and developed to obtain a patterned resin film (a resin film on which a pattern is formed). Then, a patterned cured film (a cured film on which a pattern is formed) can be formed by thermally curing the patterned resin film, and the patterned cured film can be used as an insulating film.

### CITATION LIST

### Patent Literature

Patent Literature 1: Japanese Unexamined Patent Publication No. 2008-309885
Patent Literature 2: Japanese Unexamined Patent Publication No. 2007-057595
Patent Literature 3: International Publication WO 2010/073948
Patent Literature 4: Japanese Unexamined Patent Publication No. H9-12712

### SUMMARY OF INVENTION

### Technical Problem

Metal wiring containing copper or the like is formed in a redistribution layer of a semiconductor element. From the viewpoint of preventing corrosion of metal wiring, the use of a photosensitive resin composition containing a rust inhibitor has been studied. However, in a case where the photosensitive resin composition containing a rust inhibitor is used, the metal wiring may be easily discolored. An object of the present disclosure is to provide a photosensitive resin composition, a cured product, and a semiconductor element capable of preventing discoloration of metal wiring.

### Solution to Problem

An aspect of the present disclosure relates to a photosensitive resin composition, a cured product of the photosensitive resin composition, and a semiconductor element.
[1] A photosensitive resin composition according to an aspect of the present disclosure contains a maleimide compound, a crosslinking agent, a photopolymerization initiator, and a rust inhibitor, in which the maleimide compound is a reaction product of a tetracarboxylic dianhydride (a1), an amine (a2), and a maleic anhydride (a3), and the rust inhibitor contains a compound represented by Formula (I) described later.
[2] In [1] described above, the amine (a2) may contain a dimer diamine and a second amine other than the dimer diamine.
[3] In [1] or [2] described above, at least one of the tetracarboxylic dianhydride (a1) and the amine (a2) may contain a compound having a fluorene skeleton.
[4] In any one of [1] to [3] described above, the tetracarboxylic dianhydride (a1) may include at least one of 1,3,3a,4,5,9b-hexahydro-5(tetrahydro-2,5-dioxo-3-furanyl)naphtho[1,2-C]furan-1,3-dione, 9,9-bis(3,4-dicarboxyphenyl)fluorene dianhydride, and 9,9-bis[4-(3,4-dicarboxyphenoxy)phenyl]fluorene dianhydride.
[5] In any one of [2] to [4] described above, the second amine may contain at least one of norbornanediamine and 9,9-bis[4-(4-aminophenoxy)phenyl]fluorene.
[6] A cured product according to an aspect of the present disclosure is a cured product of the photosensitive resin composition according to any one of [1] to [5] described above.
[7] A semiconductor element according to an aspect of the present disclosure includes a redistribution layer containing a cured product of the photosensitive resin composition according to any one of [1] to [5] described above.

### Advantageous Effects of Invention

According to the present disclosure, it is possible to provide a photosensitive resin composition, a cured product, and a semiconductor element capable of preventing discoloration of metal wiring.

### DESCRIPTION OF EMBODIMENTS

Hereinafter, preferred embodiments of the present disclosure will be described in detail. However, the present invention is not limited to the following embodiments, and various modifications can be made within the scope of the gist of the present invention.

In the present specification, a numerical range indicated using “to” indicates a range including numerical values described before and after “to” as a minimum value and a maximum value, respectively. In the numerical range described in stages in the present specification, an upper limit value or a lower limit value of a numerical range of a certain stage can be optionally combined with an upper limit value or a lower limit value of a numerical range of another stage. In the numerical range described in the present specification, the upper limit value or the lower limit value of the numerical range may be replaced with a value illustrated in Examples. “A or B” may include either A or B, or may include both A and B. Materials exemplified in the present specification can be used alone or in combination of two or more kinds thereof unless otherwise specified. When a plurality of materials corresponding to the respective components are present in the composition, the content of each component in the composition means the total amount of the plurality of materials present in the composition unless otherwise specified.

In the present specification, the “layer” and the “film” include not only a structure having a shape formed on the entire surface but also a structure having a shape formed on a part thereof when observed as a plan view. The term “step” includes not only an independent step but also a step that cannot be clearly distinguished from other steps as long as the intended purpose of the step is achieved.

In the present specification, “(meth)acryloyl” means at least one of “acryloyl” or “methacryloyl” corresponding thereto, and the same applies to other similar expressions such as (meth)acrylic acid and (meth)acrylate. In the present specification, the “solid content” refers to a non-volatile content excluding a volatile substance (water, a solvent, or the like) contained in a photosensitive resin composition, and also includes a component in a liquid, syrupy, or waxy state at room temperature (around 25° C.).

### [Photosensitive Resin Composition]

A photosensitive resin composition according to the present embodiment contains a maleimide compound, a crosslinking agent, a photopolymerization initiator, and a rust inhibitor. The photosensitive resin composition according to the present embodiment is a negative photosensitive resin composition, and a cured product of the photosensitive resin composition can be suitably used as an insulating film for a redistribution layer. Hereinafter, each component used in the photosensitive resin composition of the present embodiment will be described in more detail.

### (Maleimide Compound)

The maleimide compound (hereinafter, also referred to as a “component (A)”) according to the present embodiment can be obtained by reacting a tetracarboxylic dianhydride (a1) (hereinafter, also referred to as a “component (a1)”), an amine (a2) (hereinafter, also referred to as a “component (a2)”), and a maleic anhydride (a3) (hereinafter, also referred to as a “component (a3)”). That is, the component (A) is a maleimide compound obtained by reacting the component (a1), the component (a2), and the component (a3). The component (A) may have a plurality of maleimide groups in the molecule. The component (A) may be a bismaleimide compound. The component (A) can be used alone or in combination of two or more kinds thereof.

As the tetracarboxylic dianhydride serving as the component (a1), those known as a raw material of polyimide can be used. Examples of the component (a1) include: pyromellitic anhydride; 4,4′-(hexafluoroisopropylidene)diphthalic anhydride; 1,3,3a,4,5,9b-hexahydro-5-(tetrahydro-2,5-dioxo-3-furanyl)naphtho[1,2-C]furan-1,3-dione; 4,4′-oxydiphthalic dianhydride; 3,3′,4,4′-diphenylsulfone tetracarboxylic dianhydride; 3,3′,4,4′-biphenyl tetracarboxylic dianhydride; 3,3′,4,4′-benzophenone tetracarboxylic dianhydride; 4,4′-(4,4′-isopropylidenediphenoxy)diphthalic anhydride; 1,2,3,4-butane tetracarboxylic dianhydride; 1,2,3,4-cyclobutane tetracarboxylic dianhydride; 1,2,3,4-cyclopentane tetracarboxylic dianhydride; 1,2,3,4-tetramethyl-1,2,3,4-cyclobutane tetracarboxylic dianhydride; bicyclo[2.2.2]oct-7-ene-2,3,5,6-tetracarboxylic dianhydride; bis(1,3-dioxo-1,3-dihydroisobenzofuran-5-carboxylic acid) 1,4-phenylene; 9,9-bis(3,4-dicarboxyphenyl)fluorene dianhydride; 4,4′-(ethyne-1,2-diyl)diphthalic anhydride; 5-(2,5-dioxotetrahydrofuryl)-3-methyl-3-cyclohexene-1,2-dicarboxylic anhydride; dicyclohexyl-3,4,3′,4′-tetracarboxylic dianhydride; 3,4′-oxydiphthalic anhydride; 3,4′-biphthalic anhydride; norbornane-2-spiro-α-cyclopentanone-α′-spiro-2″-norbornane-5,5″,6,6″-tetracarboxylic dianhydride; 5,5′-bis-2-norbornene-5,5′,6,6′-tetracarboxylic-5,5′,6,6′-dianhydride; and 9,9-bis[4-(3,4-dicarboxyphenoxy)phenyl]fluorene dianhydride.

From the viewpoint of low dielectric characteristics or high Tg, the component (a1) may contain at least one selected from the group consisting of 1,3,3a,4,5,9b-hexahydro-5-(tetrahydro-2,5-dioxo-3-furanyl)naphtho[1,2-C]furan-1,3-dione, 9,9-bis(3,4-dicarboxyphenyl)fluorene dianhydride, 3,3′,4,4′-biphenyl tetracarboxylic dianhydride, 4,4′-(4,4′-isopropylidenediphenoxy)diphthalic anhydride, 4,4′-(hexafluoroisopropylidene)diphthalic anhydride, 5-(2,5-dioxotetrahydrofuryl)-3-methyl-3-cyclohexene-1,2-dicarboxylic anhydride, dicyclohexyl-3,4,3′,4′-tetracarboxylic dianhydride, bicyclo[2.2.2]octane-2,3,5,6-tetracarboxylic 2,3:5,6-dianhydride, 5,5′-bis-2-norbornene-5,5′,6,6′-tetracarboxylic-5,5′,6,6′-dianhydride, 3,4′-biphthalic anhydride, and 9,9-bis[4-(3,4-dicarboxyphenoxy)phenyl]fluorene dianhydride; may contain at least one selected from the group consisting of 1,3,3a,4,5,9b-hexahydro-5-(tetrahydro-2,5-dioxo-3-furanyl)naphtho[1,2-C]furan-1,3-dione, 9,9-bis(3,4-dicarboxyphenyl)fluorene dianhydride, 4,4′-(4,4′-isopropylidenediphenoxy)diphthalic anhydride, 4,4′-(hexafluoroisopropylidene)diphthalic anhydride, and 9,9-bis[4-(3,4-dicarboxyphenoxy)phenyl]fluorene dianhydride; or may contain at least one selected from the group consisting of 1,3,3a,4,5,9b-hexahydro-5-(tetrahydro-2,5-dioxo-3-furanyl)naphtho[1,2-C]furan-1,3-dione, 9,9-bis(3,4-dicarboxyphenyl)fluorene dianhydride, and 9,9-bis[4-(3,4-dicarboxyphenoxy)phenyl]fluorene dianhydride.

The component (a2) may contain a dimer diamine (first amine) and a second amine other than the dimer diamine.

The dimer diamine is, for example, a compound derived from a dimer acid which is a dimer of an unsaturated fatty acid such as oleic acid as described in Japanese Unexamined Patent Publication No. H9-12712. By using a dimer diamine serving as the component (a2), the dielectric characteristics of the cured product can be lowered. In the present embodiment, a known dimer diamine can be used without particular limitation. The dimer diamine may contain, for example, at least one of a compound represented by the following Formula (1) and a compound represented by the following Formula (2).

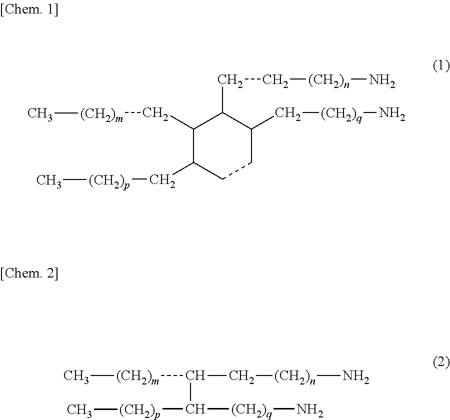

In Formulas (1) and (2), m, n, p, and q each represent an integer of 1 or more selected to satisfy m+n=6 to 17 and p+q=8 to 19, and a bond indicated by a broken line represents a carbon-carbon single bond or a carbon-carbon double bond. Provided that in a case where the bond indicated by the broken line is a carbon-carbon double bond, Formulas (1) and (2) have a structure in which the number of hydrogen atoms bonded to each carbon atom constituting the carbon-carbon double bond is subtracted by one from the numbers indicated in Formulas (1) and (2).

As the dimer diamine, a compound represented by the above Formula (2) may be used, and particularly a compound represented by the following Formula (3) may be used, from the viewpoint of solubility in an organic solvent, heat resistance, heat-resistant adhesiveness, low viscosity, and the like.

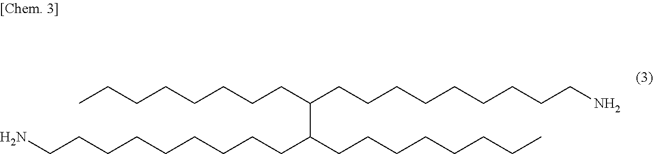 [SMILES: CCCCCCCCC(CCCCCCCCCN)C(CCCCCCCC)CCCCCCCCCN]

Examples of a commercially available product of the dimer diamine include PRIAMINE 1075 and PRIAMINE 1074 (both manufactured by Croda Japan K.K.).

The second amine is an amine that does not correspond to the dimer diamine described above. The second amine may be a diamine or a triamine. As the second amine, an alicyclic diamine may be used from the viewpoint of low dielectric constant. From the viewpoint of improving an elastic modulus and Tg of the cured product, an aromatic diamine may be used as the second amine.

In a case where the second amine is a diamine, examples of the diamine include 1,3-diaminopropane, norbornanediamine, 4,4′-methylenedianiline, 1,3-bis[2-(4-aminophenyl)-2-propyl]benzene, 4,4′-diamino-2,2′-bis(trifluoromethyl) biphenyl, 2,2-bis[4-(4-aminophenoxy)phenyl]hexafluoropropane, 9,9-bis(4-aminophenyl)fluorene, 9,9-bis(3-fluoro-4-aminophenyl)fluorene, 9,9-bis[4-(4-aminophenoxy)phenyl]fluorene, 1,3-bis(aminomethyl)cyclohexane, 1,4-bis(aminomethyl)cyclohexane, bis(aminomethyl) norbornane, 4,4′-(hexafluoroisopropylidene)di-aniline, 3(4),8(9)-bis(aminomethyl)tricyclo[5.2.1.0^{2,6}]decane, 1,3-cyclohexanediamine, 1,4-cyclohexanediamine, isophoronediamine, 4,4′-methylenebis(cyclohexylamine), 4,4′-methylenebis(2-methylcyclohexylamine), 1,1-bis(4-aminophenyl)cyclohexane, 2,7-diaminofluorene, 4,4′-ethylenedianiline, 4,4′-methylenebis(2,6-diethylaniline), 4,4′-methylenebis(2-ethyl-6-methylaniline), 2,2-bis[4-(4-aminophenoxy)phenyl]propane, bis[4-(4-aminophenoxy)phenyl]methane, 4,4′-bis(4-aminophenoxy) biphenyl, bis[4-(4-aminophenoxy)phenyl]ether, bis[4-(4-aminophenoxy)phenyl]ketone, 1,3-bis(4-aminophenoxy)benzene, 1,4-bis(4-aminophenoxy)benzene, 2,2′-dimethylbiphenyl-4,4′-diamine, (4,4′-diamino)diphenyl ether, (3,3′-diamino)diphenyl ether, para-phenylenediamine, ortho-phenylenediamine, meta-phenylenediamine, bis[4-(3-aminophenoxy)phenyl]sulfone, meta-xylylenediamine, 4,4′-diamino-2,2′-diethylbiphenyl, 4,4′-diamino-3,3′-dimethylbiphenyl, 4,4′-diamino-3,3′-diethylbiphenyl, 4,4′-diamino-3,3′,5,5′-tetramethylbiphenyl, 4,4′-diamino-3,3′,5,5′-tetraethylbiphenyl, 4,4′-diamino-2,2′-dimethoxybiphenyl, 4,4′-diamino-3,3′-dimethoxybiphenyl, and bis[4-(4-aminophenoxy)phenyl]sulfone.

In a case where the second amine is triamine, examples of the triamine include tris(2-aminomethyl)amine, tris(2-aminoethyl)amine, tris(2-aminopropyl)amine, 2-(aminomethyl)-2-methyl-1,3-propanediamine, a trimer triamine, 3,4,4′-triaminodiphenyl ether, 1,2,4-triaminobenzene, 1,3,5-triaminobenzene, 1,2,3-triaminobenzene, 1,3,5-triazine-2,4,6-triamine, 2,4,6-triaminopyrimidine, 1,3,5-tris(4-aminophenyl)benzene, and 1,3,5-tris(4-aminophenoxy)benzene. As the triamine, an aliphatic triamine may be employed from the viewpoint of the solubility of the synthesized component (A) in an organic solvent, or tris(2-aminomethyl)amine and tris(2-aminoethyl)amine having a small number of carbon atoms may be employed from the viewpoint of achieving a high Tg.

From the viewpoint of achieving a high Tg and a high elastic modulus, the second amine may contain at least one of norbornanediamine and 9,9-bis[4-(4-aminophenoxy)phenyl]fluorene.

In the component (a2), the molar ratio of the second amine to the total amount of the amines (the number of moles of the second amine/(the number of moles of the dimer diamine+the number of moles of the second amine)) may be 70 mol % or less or 50 mol % or less from the viewpoint of the low dielectric characteristics of the cured product. In a case where the second amine contains a diamine, the molar ratio of the diamine in the second amine to the total amount of the diamine in the component (a2) (the number of moles of the diamine in the second amine/(the number of moles of the dimer diamine+the number of moles of the diamine in the second amine)) may be 70 mol % or less or 50 mol % or less from the viewpoint of the low dielectric characteristics of the cured product.

By using a dimer diamine serving as the component (a2), the dielectric characteristics of the cured product can be lowered. In addition, when the second amine is used in combination with a dimer diamine, the elastic modulus and Tg can be further improved while maintaining the dielectric characteristics of the cured product.

From the viewpoint of the low dielectric constant, low dielectric loss tangent, high elastic modulus, and high Tg, at least one of the component (a1) and the component (a2) described above may contain a compound having a fluorene skeleton, and both the component (a1) and the component (a2) described above may contain a compound having a fluorene skeleton.

The component (A) can be prepared by various known methods. For example, first, the component (a1) and the component (a2) are subjected to a polyaddition reaction at a temperature of 60° C. to 120° C. or 70° C. to 90° C. for 0.1 to 2 hours or 0.1 to 1.0 hours. Next, the obtained polyaddition product is further subjected to an imidation reaction, that is, a dehydration ring-closing reaction, at a temperature of 80° C. to 250° C. or 100° C. to 200° C. for 0.5 to 30 hours or 0.5 to 10 hours. Subsequently, the product obtained by the dehydration ring-closing reaction and the component (a3) are subjected to a maleimidation reaction, that is, a dehydration ring-closing reaction, at a temperature of 60° C. to 250° C. or 80° C. to 200° C. for 0.5 to 30 hours or 0.5 to 10 hours, thereby obtaining a target component (A).

In the imidation reaction or the maleimidation reaction, various known reaction catalysts, dehydrating agents, and organic solvents can be used.

Examples of the reaction catalyst include aliphatic tertiary amines such as triethylamine, aromatic tertiary amines such as dimethylaniline, heterocyclic tertiary amines such as pyridine, picoline, and isoquinoline, and organic acids such as methanesulfonic acid and p-toluenesulfonic acid monohydrate. Examples of the dehydrating agent include aliphatic acid anhydrides such as acetic anhydride and aromatic acid anhydrides such as benzoic anhydride.

Examples of the organic solvent include aromatic hydrocarbons such as benzene, toluene, xylene, mesitylene, and pseudocumene; alcoholic solvents such as methanol, ethanol, isopropyl alcohol, butanol, pentanol, hexanol, propanediol, and phenol; ketone solvents such as acetone, methyl isobutyl ketone, methyl ethyl ketone, pentanone, hexanone, cyclopentanone, cyclohexanone, isophorone, and acetophenone; cellosolves such as methyl cellosolve and ethyl cellosolve; ester-based solvents such as methyl acetate, ethyl acetate, butyl acetate, methyl propionate, butyl formate, and γ-butyrolactone; glycol ether-based solvents such as ethylene glycol mono-n-butyl ether, ethylene glycol mono-iso-butyl ether, ethylene glycol mono-tert-butyl ether, diethylene glycol mono-n-butyl ether, diethylene glycol mono-iso-butyl ether, triethylene glycol mono-n-butyl ether, and tetraethylene glycol mono-n-butyl ether; and nitrogen-containing compounds such as N,N-dimethylformamide, N,N-dimethylacetamide, N-methyl-2-pyrrolidone, N-ethyl-2-pyrrolidone, 3-methoxy-N,N-dimethylpropanamide, and 3-butoxy-N,N-dimethylpropanamide. The organic solvent can be used alone or in combination of two or more kinds thereof.

The component (A) can be purified by various known methods, and the purity can be increased. For example, first, the component (A) dissolved in an organic solvent and pure water are placed in a separatory funnel. Next, the separatory funnel is shaken and allowed to stand. Subsequently, after an aqueous layer and an organic layer are separated, only the organic layer is recovered, such that the component (A) can be purified.

An assumed structure of the component (A) produced by the above method is represented by the following Formula (4).

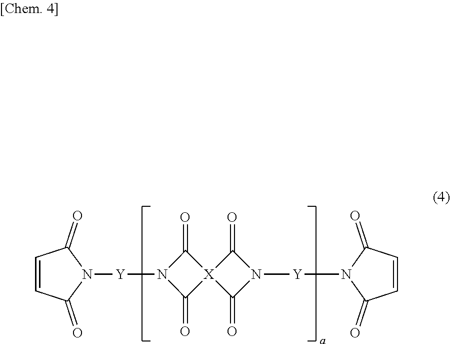

In Formula (4), each X independently represents a tetravalent organic group, each Y independently represents a divalent organic group, and a is an integer of 1 or more. Y represents a divalent organic group derived from the component (a2). In a case where the dimer diamine described above and the diamine serving as the second amine other than the dimer diamine are used as the component (a2), at least one of a plurality of Ys represents a divalent organic group derived from the dimer diamine described above, and at least one of the plurality of Ys represents a divalent organic group derived from the second amine described above. In addition, X and Y may be organic groups having an aliphatic group, a cycloaliphatic structure, or an aromatic ring, and these may contain heteroatoms.

A molecular weight of the component (A) can be controlled by the number of moles of the component (a1) and the number of moles of the component (a2), and the molecular weight can be made smaller as the number of moles of the component (a1) is smaller than the number of moles of the component (a2). The number of moles of the component (a1) per mole of the component (a2), that is, [the number of moles of the component (a1)]/[the number of moles of the component (a2)], may be 0.30 to 0.98, 0.30 to 0.90, 0.50 to 0.90, 0.60 to 0.90, or 0.60 to 0.80.

The weight-average molecular weight (Mw) of the component (A) may be 3000 to 40000, 4000 to 30000, 5000 to 28000, or 7000 to 27000 from the viewpoint of solubility in a solvent and heat resistance. The Mw can be measured by gel permeation chromatography (GPC), and can be converted using a calibration curve of standard polystyrene.

The content of the component (A) may be 50 parts by mass or more, 60 parts by mass or more, 70 parts by mass or more, or 80 parts by mass or more when the total amount of the component (A) and a component (B) described later is 100 parts by mass.

### (Crosslinking Agent)

A crosslinking agent (hereinafter, also referred to as a “component (B)”) may be a polymerizable crosslinking agent. The polymerizable group may be a photopolymerizable group or a thermopolymerizable group. Examples of the polymerizable group include a (meth)acryloyl group, an allyl group, and a vinyl group. The component (B) may be a polyfunctional compound having two or more polymerizable groups. The component (B) can be crosslinked, for example, not only with other crosslinking agents but also with the component (A) during exposure of the photosensitive layer. The component (B) can be crosslinked, for example, with other polymerizable crosslinking agents during heating of the resin film after pattern formation. The component (B) can be used alone or in combination of two or more kinds thereof.

The component (B) may contain a polymerizable crosslinking agent having a (meth)acryloyl group from the viewpoint of dielectric characteristics. The polymerizable crosslinking agent having a (meth)acryloyl group can crosslink not only with other crosslinking agents but also with the component (A) during exposure of the photosensitive layer. The polymerizable crosslinking agent having a (meth)acryloyl group may be an acrylate compound or a methacrylate compound. The component (B) may include a methacrylate compound from the viewpoint of dielectric characteristics.

Examples of the polymerizable crosslinking agent having a (meth)acryloyl group include tricyclodecanedimethanol di(meth)acrylate, tris(2-(meth)acryloyloxyethyl)isocyanurate, dioxane glycol di(meth)acrylate, alkoxylated glycerin tri(meth)acrylate, trimethylolpropane tri(meth)acrylate, alkoxylated trimethylolpropane tri(meth)acrylate, pentaerythritol tri(meth)acrylate, pentaerythritol tetra(meth)acrylate, alkoxylated pentaerythritol tetra(meth)acrylate, 1,6-hexanediol di(meth)acrylate, 1,9-nonanediol di(meth)acrylate, 1,10-decanediol di(meth)acrylate, neopentyl glycol di(meth)acrylate, ethoxylated bisphenol A di(meth)acrylate, propoxylated ethoxylated bisphenol A (meth)acrylate, dipentaerythritol poly(meth)acrylate, alkoxylated dipentaerythritol poly(meth)acrylate, ethoxylated isocyanuric acid tri(meth)acrylate, polyethylene glycol di(meth)acrylate, and polypropylene glycol di(meth)acrylate.

The polymerizable crosslinking agent having a (meth)acryloyl group may include at least one selected from the group consisting of tricyclodecanedimethanol di(meth)acrylate, tris(2-(meth)acryloyloxyethyl)isocyanurate, and dioxane glycol di(meth)acrylate from the viewpoint of heat resistance, dielectric characteristics, and fine processability, and may include tris(2-(meth)acryloyloxyethyl)isocyanurate from the viewpoint of heat resistance and dielectric characteristics.

The component (B) may contain a polymerizable crosslinking agent having an allyl group or a vinyl group from the viewpoint of dielectric characteristics and heat resistance. The polymerizable crosslinking agent having an allyl group or a vinyl group can crosslink with other polymerizable crosslinking agents during heating of the resin film after pattern formation.

Examples of the polymerizable crosslinking agent having an allyl group include 1,3,4,6-tetraallyl glycoluril, triallyl isocyanurate, diallyl monoglycidyl isocyanurate, diallyl monomethyl isocyanurate, diallyl isocyanurate, triallyl trimellitate, and triallyl ortho-formate.

Examples of the polymerizable crosslinking agent having a vinyl group include a polyvinyl benzyl compound and a polyvinyl benzyl ether compound.

The polymerizable crosslinking agent having an allyl group or a vinyl group may include at least one selected from the group consisting of 1,3,4,6-tetraallyl glycoluril, triallyl isocyanurate, diallyl isocyanurate, and a polyvinyl benzyl ether compound from the viewpoint of dielectric characteristics and fine processability, and may include triallyl isocyanurate from the viewpoint of dielectric characteristics.

From the viewpoint of improving a balance between the low dielectric characteristics and the fine processability, the content of the component (B) may be 1 to 45 parts by mass, 5 to 40 parts by mass, 8 to 30 parts by mass, or 10 to 20 parts by mass, when the total amount of the components (A) and (B) is 100 parts by mass.

### (Photopolymerization Initiator)

The photopolymerization initiator (hereinafter, also referred to as a “component (C)”) is not particularly limited as long as it is a compound that initiates polymerization by radiation with an active ray (ultraviolet ray or the like), and examples thereof include an alkylphenone-based photopolymerization initiator, an acylphosphine oxide-based photopolymerization initiator, an intramolecular hydrogen abstraction type photopolymerization initiator, and an oxime ester-based photopolymerization initiator.

The alkylphenone-based photopolymerization initiator can be purchased as, for example, Omnirad 651, Omnirad 184, Omnirad 1173, Omnirad 2959, Omnirad 127, Omnirad 907, Omnirad 369, or Omnirad 379EG manufactured by IGM Resins B.V., or the like. The acylphosphine oxide-based photopolymerization initiator can be purchased as, for example, Omnirad 819 or Omnirad TPO H manufactured by IGM Resins B.V., or the like. The intramolecular hydrogen abstraction type photopolymerization initiator can be purchased as, for example, Omnirad MBF or Omnirad 754 manufactured by IGM Resins B.V., or the like. The oxime ester-based photopolymerization initiator can be purchased as, for example, Irgacure OXE01 or Irgacure OXE02 manufactured by BASF Japan Ltd., or the like. In order to promote the photoreaction, a titanocene-based photopolymerization initiator (for example, Irgacure 784, manufactured by BASF Japan Ltd.) may be used in combination.

The content of the component (C) may be 0.1 to 10 parts by mass, 0.5 to 8 parts by mass, or 1 to 5 parts by mass, with respect to 100 parts by mass of the total amount of the component (A) and the component (B) from the viewpoint of achieving excellent fine processability.

### (Rust Inhibitor)

The rust inhibitor (hereinafter, also referred to as a “component (D)”) contains a compound represented by the following Formula (I). The photosensitive resin composition according to the present embodiment can prevent discoloration of metal wiring by using the above-described specific compound as a rust inhibitor. The component (D) can be used alone or in combination of two or more kinds thereof.

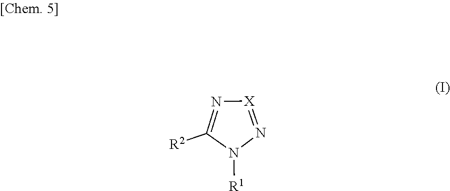

In Formula (I), X represents a carbon atom or a nitrogen atom, and R¹ and R² each independently represent a hydrogen atom, an alkyl group, an aryl group, or a nitrogen-containing group. In a case where X represents a nitrogen atom, R¹ and R² do not both represent a hydrogen atom. From the viewpoint of preventing discoloration, in Formula (I), X may represent a nitrogen atom, R¹ may represent a hydrogen atom, and R² may represent a nitrogen-containing group.

The number of carbon atoms in the alkyl group may be 1 to 6, 1 to 4, or 1 to 3. The alkyl group may be linear or branched. Examples of the alkyl group include a methyl group, an ethyl group, and a propyl group.

The number of carbon atoms in the aryl group may be 6 to 10 or 6 to 8. Examples of the aryl group include a phenyl group and a benzyl group.

Examples of the nitrogen-containing group include a group represented by the following Formula (I-1) and an amino group (NH₂ group). From the viewpoint of preventing discoloration, the nitrogen-containing group may be an amino group.

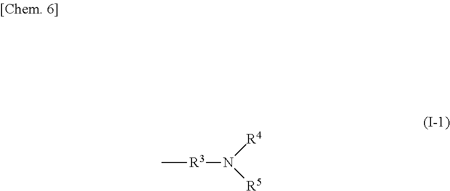

In Formula (I-1), R³ represents an alkylene group, and R⁴ and R⁵ each independently represent an alkyl group. The number of carbon atoms of the alkylene group represented by R³ may be 1 to 3 or 1 to 2. The number of carbon atoms of the alkyl group represented by R⁴ and R⁵ may be 1 to 15, 3 to 12, or 5 to 10. The alkyl group represented by R⁴ and R⁵ may be linear or branched. R⁴ and R⁵ may be the same as or different from each other. From the viewpoint of preventing discoloration, R⁴ and R⁵ may be the same as each other. Examples of the group represented by Formula (I-1) include —CH₂—N(C₈H₁₇)₂.

From the viewpoint of preventing discoloration, in a case where X is a carbon atom, in Formula (I), R¹ may be a group represented by Formula (I-1), and R² may be a hydrogen atom. From the viewpoint of preventing discoloration, in a case where X is a nitrogen atom, in Formula (I), R¹ may be a hydrogen atom and R² may be an amino group.

As the component (D), a commercially available product may be used. Examples of commercially available products of the component (D) include HAT (product name, 5-amino-1H-tetrazole, manufactured by TOYOBO MC Corporation) and TA-LX (product name, 1-bis(2-ethylhexyl)aminomethyl-1,2,4-triazole, manufactured by Johoku Chemical Co., Ltd.).

The content of the component (D) may be 0.01 mass % or more, 0.10 mass % or more, 0.50 mass % or more, or 1.0 mass % or more, and may be 10.0 mass % or less, 8.0 mass % or less, 6.0 mass % or less, or 5.0 mass % or less, based on the mass (total mass of solid content) of all components except the solvent in the photosensitive resin composition. The content of the component (D) may be 0.01 mmol/g or more, 0.05 mmol/g or more, 0.10 mmol/g or more, 0.12 mmol/g or more, 0.16 mmol/g or more, or 0.18 mmol/g or more, and may be 3.0 mmol/g or less, 1.0 mmol/g or less, or 0.5 mmol/g or less, based on the total mass of solid content in the photosensitive resin composition.

The photosensitive resin composition according to the present embodiment may further contain a coupling agent, a polymerization inhibitor, a thermal polymerization initiator, and the like as necessary.

### (Coupling Agent)

The photosensitive resin composition according to the present embodiment may further contain a coupling agent (hereinafter, also referred to as a “component (E)”) from the viewpoint of improving the adhesion of the cured product of the photosensitive resin composition. The coupling agent may be a silane coupling agent. The silane coupling agent may have, for example, a group such as a vinyl group, an epoxy group, a styryl group, an acryloyl group, a methacryloyl group, an amino group, a ureido group, an isocyanate group, an isocyanurate group, or a mercapto group.

Examples of the silane coupling agent having a vinyl group include KBM-1003 and KBE-1003 (product name, manufactured by Shin-Etsu Chemical Co., Ltd.; the same applies hereinafter). Examples of the silane coupling agent having an epoxy group include KBM-303, 402, and 403, KBE-402 and 403, X-12-981S, and X-12-984S. Examples of the silane coupling agent having a styryl group include KBM-1403. Examples of the silane coupling agent having a methacryloyl group include KBM-502 and 503 and KBE-502 and 503. Examples of the silane coupling agent having an acryloyl group include KBM-5103, X-12-1048, and X-12-1050. Examples of the silane coupling agent having an amino group include KBM-602, 603, 903, 573, and 575, KBE-903 and 9103P, and X-12-972F. Examples of the silane coupling agent having a ureido group include KBE-585. Examples of the silane coupling agent having an isocyanate group include KBE-9007 and X-12-1159L. Examples of the silane coupling agent having an isocyanurate group include KBM-9659. Examples of the silane coupling agent having a mercapto group include KBM-802 and 803, X-12-1154, and X-12-1156. The silane coupling agent may be a silane coupling agent having a methacryloyl group. The silane coupling agents can be used alone or in combination with two or more kinds thereof.

The content of the silane coupling agent may be 0.01 to 10 parts by mass, 0.1 to 8 parts by mass, or 0.5 to 5 parts by mass, with respect to 100 parts by mass of the total amount of the component (A) and the component (B).

### (Polymerization Inhibitor)

The photosensitive resin composition according to the present embodiment may further contain a polymerization inhibitor (hereinafter, also referred to as a “component (F)”) from the viewpoint of storage stability. Examples of the polymerization inhibitor include 4-tert-butylcatechol, 4-hydroxy-2,2,6,6-tetramethylpiperidine-1-oxy radical, p-methoxyphenol, diphenyl-p-benzoquinone, benzoquinone, hydroquinone, pyrogallol, phenothiazine, resorcinol, ortho-dinitrobenzene, para-dinitrobenzene, meta-dinitrobenzene, phenanthraquinone, N-phenyl-2-naphthylamine, cupferron, 2,5-toluquinone, tannic acid, para-benzylaminophenol, tris(4-tert-butyl-3-hydroxy-2,6-dimethylbenzyl) isocyanuric acid, and nitrosamines. The polymerization inhibitor may be used alone or in combination of two or more kinds thereof.

The content of the polymerization inhibitor may be 0.01 to 10 parts by mass, 0.05 to 5 parts by mass, or 0.10 to 2 parts by mass, with respect to 100 parts by mass of the total amount of the component (A) and the component (B).

### (Thermal Polymerization Initiator)

The photosensitive resin composition according to the present embodiment may further contain a thermal polymerization initiator from the viewpoint of promoting a polymerization reaction of a thermally polymerizable crosslinking agent. As the thermal polymerization initiator, a compound that is decomposed by heating during curing to generate radicals and promotes the polymerization reaction of the component (A) and the component (B) may be used. Examples of the thermal polymerization initiator include an organic peroxide.

Examples of the organic peroxide include methyl ethyl ketone peroxide, methylcyclohexanone peroxide, methyl acetoacetate peroxide, acetylacetone peroxide, 1,1-bis(t-butylperoxy)-3,3,5-trimethylcyclohexane, 1,1-bis(t-hexylperoxy)cyclohexane, 1,1-bis(t-hexylperoxy)-3,3,5-trimethylcyclohexane, 1,1-bis(t-butylperoxy)cyclohexane, 2,2-bis(4,4-di-t-butylperoxycyclohexyl) propane, 1,1-bis(t-butylperoxy)cyclododecane, n-butyl 4,4-bis(t-butylperoxy) valerate, 2,2-bis(t-butylperoxy) butane, 1,1-bis(t-butylperoxy)-2-methylcyclohexane, t-butyl hydroperoxide, p-menthane hydroperoxide, 1,1,3,3-tetramethylbutyl hydroperoxide, t-hexyl hydroperoxide, dicumyl peroxide, 2,5-dimethyl-2,5-bis(t-butylperoxy) hexane, α,α′-bis(t-butylperoxy)diisopropylbenzene, t-butylcumyl peroxide, di-t-butyl peroxide, 2,5-dimethyl-2,5-bis(t-butylperoxy) hexyne-3, isobutyryl peroxide, 3,5,5-trimethylhexanoyl peroxide, octanoyl peroxide, lauroyl peroxide, cinnamic acid peroxide, m-toluoyl peroxide, benzoyl peroxide, diisopropyl peroxydicarbonate, bis(4-t-butylcyclohexyl) peroxydicarbonate, di-3-methoxybutyl peroxydicarbonate, di-2-ethylhexyl peroxydicarbonate, di-sec-butyl peroxydicarbonate, di(3-methyl-3-methoxybutyl) peroxydicarbonate, di(4-t-butylcyclohexyl) peroxydicarbonate, α,α′-bis(neodecanoylperoxy)diisopropylbenzene, cumylperoxyneodecanoate, 1,1,3,3-tetramethylbutylperoxyneodecanoate, 1-cyclohexyl-1-methylethyl peroxyneodecanoate, t-hexylperoxyneodecanoate, t-butylperoxyneodecanoate, t-hexylperoxypivalate, t-butylperoxypivalate, 2,5-dimethyl-2,5-bis(2-ethylhexanoylperoxy) hexane, 1,1,3,3-tetramethylbutylperoxy-2-ethylhexanoate, 1-cyclohexyl-1-methylethylperoxy-2-ethylhexanoate, t-hexylperoxy-2-ethylhexanoate, t-butylperoxy-2-ethylhexanoate, t-butylperoxyisobutyrate, t-butylperoxymaleic acid, t-butylperoxylaurate, t-butylperoxy-3,5,5-trimethylhexanoate, t-butylperoxyisopropyl monocarbonate, t-butylperoxy-2-ethylhexyl monocarbonate, 2,5-dimethyl-2,5-bis(benzoylperoxy) hexane, t-butylperoxyacetate, t-hexylperoxybenzoate, t-butylperoxy-m-toluoyl benzoate, t-butylperoxybenzoate, bis(t-butylperoxy) isophthalate, t-butylperoxyallyl monocarbonate, and 3,3′,4,4′-tetra(t-butylperoxycarbonyl)benzophenone.

The content of the thermal polymerization initiator is not particularly limited, and may be 0.1 to 10.0 parts by mass, 0.5 to 5.0 parts by mass, or 0.7 to 3.0 parts by mass, with respect to 100 parts by mass of the total amount of the component (A) and the component (B).

### (Sensitizer)

The photosensitive resin composition according to the present embodiment may further contain a sensitizer from the viewpoint of achieving both maintenance of a residual film ratio in a wide range of exposure doses and excellent resolution. The sensitizer may be used alone or in combination of two or more kinds thereof.

Examples of the sensitizer include Michler's ketone, benzoin, 2-methylbenzoin, benzoin methyl ether, benzoin ethyl ether, benzoin isopropyl ether, benzoin butyl ether, 2-t-butylanthraquinone, 1,2-benzo-9,10-anthraquinone, anthraquinone, methyl anthraquinone, 4,4′-bis(diethylamino)benzophenone, acetophenone, benzophenone, thioxanthone, 1,5-acenaphthene, 2,2-dimethoxy-2-phenylacetophenone, 1-hydroxycyclohexyl phenyl ketone, 2-methyl-[4-(methylthio)phenyl]-2-morpholino-1-propanone, diacetylbenzyl, benzyl dimethyl ketal, benzyl diethyl ketal, diphenyl disulfide, anthracene, phenanthrenequinone, riboflavin tetrabutyrate, acridine orange, erythrosine, phenanthrenequinone, 2-isopropylthioxanthone, 2,6-bis(p-diethylaminobenzylidene)-4-methyl-4-azacyclohexanone, 6-bis(p-dimethylaminobenzylidene)cyclopentanone, 2,6-bis(p-diethylaminobenzylidene)-4-phenylcyclohexanone, aminostyryl ketone, 3-ketocoumarin compounds, biscoumarin compounds, N-phenylglycine, N-phenyldiethanolamine, and 3,3′,4,4′-tetra(t-butylperoxycarbonyl)benzophenone.

In a case where the photosensitive resin composition contains a sensitizer, the content thereof may be 0.1 to 2.0 parts by mass, or may be 0.2 to 1.5 parts by mass, with respect to 100 parts by mass of the component (A).

### (Solvent)

When the photosensitive resin composition according to the present embodiment contains a solvent for dissolving and dispersing each component, the photosensitive resin composition can be easily applied onto a substrate to form a coating film having a uniform thickness. The solvent may be used alone or in combination of two or more kinds thereof.

Examples of the solvent include ketones such as methyl ethyl ketone, cyclohexanone, and cyclopentanone; aromatic hydrocarbons such as toluene, xylene, tetramethylbenzene, pseudocumene, and mesitylene; glycol ethers such as methyl cellosolve, butyl cellosolve, methyl carbitol, butyl carbitol, propylene glycol monomethyl ether, dipropylene glycol monoethyl ether, dipropylene glycol dimethyl ether, dipropylene glycol diethyl ether, and triethylene glycol monoethyl ether; esters such as ethyl acetate, butyl acetate, butyl cellosolve acetate, carbitol acetate, and γ-butyrolactone; and nitrogen-containing compounds such as N,N-dimethylformamide, N,N-dimethylacetamide, N-methyl-2-pyrrolidone, N-ethyl-2-pyrrolidone, 3-methoxy-N,N-dimethylpropanamide, and 3-butoxy-N,N-dimethylpropanamide.

A blending amount of the solvent is not particularly limited, and may be an amount in which a solid content in the photosensitive resin composition is 5 to 60 mass %, 10 to 50 mass %, or 15 to 40 mass %.

The preparation means, conditions, and the like of the photosensitive resin composition are not particularly limited. Examples thereof include a method in which the respective main components are sufficiently uniformly stirred and mixed in predetermined blending amounts by a mixer or the like, and then kneaded by using a mixing roll, an extruder, a kneader, a roll, an extruder, or the like. The kneading method is not particularly limited.

The photosensitive resin composition according to the present embodiment can prevent discoloration of metal wiring. By using the photosensitive resin composition according to the present embodiment, a semiconductor element including an interlayer insulating layer formed using a cured product of the photosensitive resin composition described above, and an electronic device including the semiconductor element can be produced. The semiconductor element may include a redistribution layer containing the cured product of the photosensitive resin composition according to the present embodiment. The semiconductor element may be, for example, a memory, a package, or the like having a multilayer wiring structure, a redistribution structure, or the like. Examples of the electronic device include a mobile phone, a smartphone, a tablet terminal, a personal computer, and a hard disk suspension.

### EXAMPLES

Hereinafter, the present disclosure will be described in more detail with reference to Examples, but the present invention is not limited to these Examples.

### Synthesis of Maleimide Compound

### Synthesis Example 1

Into a 1 L flask vessel equipped with a cooler, a nitrogen inlet tube, a thermocouple, a stirrer, and a vacuum pump, 96.28 parts by mass of 9,9-bis(3,4-dicarboxyphenyl)fluorene dianhydride (trade name “BPAF” manufactured by JFE Chemical Corporation), 385.55 parts by mass of pseudocumene (manufactured by Toyo Gosei Co., Ltd.), 86.50 parts by mass of Solmix A-11 (trade name, manufactured by JAPAN ALCOHOL TRADING CO., LTD., alcohol-based solvent containing ethanol as a main agent), and 90.50 parts by mass of γ-butyrolactone (manufactured by FUJIFILM Wako Pure Chemical Corporation) were charged. After charging, the temperature was raised to 80° C. and maintained for 0.5 hours, and 90.21 parts by mass of a dimer diamine (DDA) (trade name “PRIAMINE 1075”, manufactured by Croda Japan K.K.) was added dropwise. After the dropwise addition, 17.28 parts by mass of norbornanediamine (NBDA) (manufactured by Mitsui Fine Chemicals, Inc.) was added dropwise. Thereafter, the mixture was maintained at 80° C. for about 0.25 hours. After maintaining the temperature, 3.79 parts by mass of a methanesulfonic acid aqueous solution (trade name “Lutropur MSA”, manufactured by BASF SE) were added. Thereafter, the temperature was raised to 160° C. After the temperature was raised, the pressure was reduced from the atmospheric pressure by 0.03 MPa, and a dehydration ring-closing reaction was performed in a reduced pressure state at 160° C. for 2 hours to remove water and alcohol in the reaction solution, thereby obtaining an intermediate polyimide resin (imidization step). Subsequently, the inside of the reaction vessel was brought to atmospheric pressure, the obtained polyimide resin was cooled to 130° C., 20.59 parts by mass of maleic anhydride (manufactured by FUSO CHEMICAL CO., LTD.) was added, the temperature was raised to 160° C., and a dehydration ring-closing reaction was performed at 160° C. for 4 hours in a state where the pressure was reduced from the atmospheric pressure by 0.03 MPa to remove water in the reaction solution, thereby obtaining a maleimide compound (maleimidation step).

The obtained maleimide compound was charged into a separatory funnel, 500 parts by mass of pure water were added thereto, and the separatory funnel was shaken and allowed to stand. After the standing, an aqueous layer and an organic layer were separated, followed by recovering only the organic layer. The recovered organic layer was charged into a 0.3 L glass vessel equipped with a condenser, a nitrogen introducing tube, a thermocouple, a stirrer, and a vacuum pump, the temperature was raised to 88 to 93° C., and then, water was removed. Thereafter, the temperature was raised to 100° C., and the solvent was partially removed for 0.5 hours in a state where the pressure was reduced from the atmospheric pressure by 0.1 MPa, thereby obtaining a solution (40 mass % of non-volatile content) of a maleimide compound (A-1) as a component (A). The Mw of the maleimide compound (A-1) was 9000.

### Synthesis Example 2

Into a 0.3 L flask vessel equipped with a cooler, a nitrogen inlet tube, a thermocouple, a stirrer, and a vacuum pump, 18.48 parts by mass of 9,9-bis(3,4-dicarboxyphenyl)fluorene dianhydride (trade name “BPAF” manufactured by JFE Chemical Corporation), 8.80 parts by mass of pyromellitic anhydride (manufactured by Daicel Corporation), 125.9 parts by mass of pseudocumene (manufactured by Toyo Gosei Co., Ltd.), 33.6 parts by mass of Solmix A-11 (trade name, manufactured by JAPAN ALCOHOL TRADING CO., LTD., alcohol-based solvent containing ethanol as a main agent), and 33.25 parts by mass of γ-butyrolactone (manufactured by FUJIFILM Wako Pure Chemical Corporation) were charged. After charging, the temperature was raised to 80° C. and maintained for 0.5 hours, and 27.57 parts by mass of a dimer diamine (DDA) (trade name: “PRIAMINE 1075”, manufactured by Croda Japan KK), 10.85 parts by mass of 2,2′-dimethylbiphenyl-4,4′-diamine (trade name “m-TB-HG” manufactured by Wakayama Seika Kogyo Co., Ltd.), and 0.52 parts by mass of tris(2-aminoethyl)amine (Tokyo Chemical Industry Co., Ltd.) were added thereto. Thereafter, the mixture was maintained at 80° C. for about 0.25 hours. After maintaining the temperature, 2.70 parts by mass of a methanesulfonic acid aqueous solution (trade name “Lutropur MSA”, manufactured by BASF SE) was added. Thereafter, the temperature was raised to 160° C. After the temperature was raised, the pressure was reduced from the atmospheric pressure by 0.03 MPa, and a dehydration ring-closing reaction was performed in the reduced pressure state at 160° C. for 3 hours to remove water and alcohol in the reaction solution, thereby obtaining an intermediate polyimide resin (imidization step). Subsequently, the inside of the reaction vessel was brought to atmospheric pressure, the obtained polyimide resin was cooled to 130° C., 7.93 parts by mass of maleic anhydride (manufactured by FUSO CHEMICAL CO., LTD.) was added, the temperature was raised to 160° C., and a dehydration ring-closing reaction was performed at 160° C. for 4 hours in a state where the pressure was reduced from the atmospheric pressure by 0.03 MPa to remove water in the reaction solution, thereby obtaining a maleimide compound (maleimidation step).

The obtained maleimide compound was charged into a separatory funnel, 500 parts by mass of pure water were added thereto, and the separatory funnel was shaken and allowed to stand. After the standing, an aqueous layer and an organic layer were separated, followed by recovering only the organic layer. The recovered organic layer was charged into a 0.3 L glass vessel equipped with a condenser, a nitrogen introducing tube, a thermocouple, a stirrer, and a vacuum pump, the temperature was raised to 88 to 93° C., and then, water was removed. Thereafter, the temperature was raised to 100° C., and the solvent was partially removed for 0.5 hours in a state where the pressure was reduced from the atmospheric pressure by 0.1 MPa, thereby obtaining a solution (44.4 mass % of non-volatile content) of a maleimide compound (A-2) as a component (A). The Mw of the maleimide compound (A-2) was 12000.

### (Non-Volatile Content)

0.75 g±0.25 g of the solution of the maleimide compound was weighed on a metal petri dish with a precision balance, and then dried at 150° C. for 0.5 hours with a hot air dryer, and the non-volatile content (NV) was calculated using the following equation.

$$NV ( mass \% ) = \{ ( W 3 - W 1 ) / W 2 \} \times 100$$

W1: mass (g) of empty metal petri dish
W2: mass (g) of solution of maleimide compound before drying
W3: mass (g) of metal petri dish+maleimide compound after drying

### (Weight-Average Molecular Weight)

The Mw of the maleimide compound was measured by gel permeation chromatography (GPC). 50 μL of a sample obtained by dissolving the maleimide compound in tetrahydrofuran (THF) so as to have a concentration of 3 mass % was injected into columns (GL-R420×1, GL-R430×1, and GL-R440×1 (all columns are manufactured by Hitachi High-Tech Fielding Corporation) heated to 30° C., and the measurement was performed under the condition of a flow rate of 1.6 mL/min using THE as a developing solvent. Note that, as a detector, L-3350 RI detector (manufactured by Hitachi, Ltd.) was used, and the Mw was converted from the elution time by a molecular weight/elution time curve created using standard polystyrene (manufactured by Tosoh Corporation).

### [Photosensitive Resin Composition]

The respective components in the blending amounts (parts by mass, solid content) illustrated in Table 1 and a solvent (mesitylene, 210 parts by mass) were mixed, and the mixture was stirred at 25° C. for 30 minutes or longer and then filtered through a filter with a mesh size of 0.5 μm, thereby preparing photosensitive resin compositions. Note that the blending amounts of the component (D) and the component (D)′ illustrated in Table 1 were expressed in millimoles (mmol) per 1 g of the total mass of solid content in the photosensitive resin composition.

Details of each component illustrated in Table 1 are as follows.
A-1: Maleimide compound (A-1) synthesized in Synthesis Example 1
A-2: Maleimide compound (A-2) synthesized in Synthesis

### Example 2

A-9300: Tris(2-acryloyloxyethyl)isocyanurate (product name, manufactured by SHIN-NAKAMURA CHEMICAL CO., LTD.)
TAIC: Triallyl isocyanurate (product name, manufactured by Mitsubishi Chemical Corporation)
A-DOG: Dioxane glycol diacrylate (product name, manufactured by SHIN-NAKAMURA CHEMICAL CO., LTD.)
OXE01: Oxime ester-based photopolymerization initiator (product name: Irgacure OXE01, manufactured by BASF Japan Ltd.)
OXE02: Oxime ester-based photopolymerization initiator (product name: Irgacure OXE02, manufactured by BASF Japan Ltd.)
HAT: 5-Amino-1H-tetrazole (product name, manufactured by TOYOBO MC Corporation)
TA-LX: 1-Bis(2-ethylhexyl)aminomethyl-1,2,4-triazole (product name, manufactured by Johoku Chemical Co., Ltd.)
BT-120SG: 1,2,3-Benzotriazole (product name, manufactured by Johoku Chemical Co., Ltd.)
BT-LX: 1-[N,N-bis(2-ethylhexyl)aminomethyl]benzotriazole (product name, manufactured by Johoku Chemical Co., Ltd.)
KBM-503:3-Methacryloxypropyltrimethoxysilane (product name, manufactured by Shin-Etsu Chemical Co., Ltd.)
TEMPOL: 4-Hydroxy-2,2,6,6-tetramethylpiperidine-1-oxy radical (product name, manufactured by Tokyo Chemical Industry Co., Ltd.)

### [Evaluation]

A silicon wafer A with a Cu sputtered film was spin-coated with the photosensitive resin composition, and was dried by heating at 70° C. for 3 minutes using a hot plate to form a resin film having a thickness of 7 μm. Subsequently, pattern exposure was performed to form a resin film having a width of 1 mm under the condition of an exposure dose of 1000 mJ/cm², using a mask aligner-exposure machine (MA-20 manufactured by Mikasa Co., Ltd.) and a band-pass filter for a mercury emission line of 365 nm (100 mm×100 mm, thickness 2.2 mm, manufactured by Asahi Spectra Co., Ltd.), followed by heating at 100° C. for 1 minute using a hot plate. After the exposed resin film was immersed twice for 15 seconds each at 25° C. in a developing solution (mixed solution of cyclopentanone and propylene glycol monomethyl ether acetate), the resin film was washed with propylene glycol monomethyl ether acetate, and cured at 200° C. for 2 hours under a nitrogen atmosphere, thereby obtaining a silicon wafer B with a Cu sputtered film, on which a cured film (insulating film) having a pattern was formed.

Using a digital microscope VHX-6000 (manufactured by Keyence Corporation; illumination: coaxial epi-illumination; lens: ZS20; magnification: 20×), the Cu-sputtered film side of the silicon wafer B (the portion where copper was exposed by development) was observed, and an image of Cu not covered with the insulating film was obtained. Next, the RGB values of the obtained Cu image (hereinafter, also referred to as “the RGB values of the processed Cu”) were obtained using the “eyedropper tool” (shutter speed: auto 70) of Microsoft Power Point (PowerPoint 2016). The RGB values of the processed Cu and the RGB values of the Cu formed on the silicon wafer A (hereinafter, also referred to as “the RGB values of the Cu before processing”) were regarded as three-dimensional coordinates, and a distance d therebetween was calculated by the following Equation (1). The smaller the value of d is, the better the discoloration resistance is.

$$d = {\{ {( {R}_{s} - {R}_{c u} )}^{2} + {( {G}_{s} - {G}_{c u} )}^{2} + {( {B}_{s} - {B}_{c u} )}^{2} \}}^{1 / 2} \qquad ( Equation 1 )$$

In Equation 1, Rₛ, Gₛ, and Bₛ represent the RGB values of the processed Cu, R_{cu}, G_{cu}, and B_{cu} represent the RGB values of the Cu before processing; R_{cu} was 227, Gou was 186, and B_{cu} was 160.

TABLE 1

| | | Example | Example | Example | Example | Comparative | Comparative |
|---|---|---|---|---|---|---|---|
| | | 1 | 2 | 3 | 4 | Example 1 | Example 2 |
| Component (A) | A-1 | 85 | 85 | — | — | 85 | 85 |
| | A-2 | — | — | 70 | 70 | — | — |
| Component (B) | A-9300 | 5 | 5 | — | — | 5 | 5 |
| | TAIC | 10 | 10 | 25 | 25 | 10 | 10 |
| | A-DOG | — | — | 5 | 5 | — | — |
| Component (C) | OXE01 | 3 | 3 | 7 | 7 | 3 | 3 |
| | OXE02 | 2 | 2 | 2 | 2 | 2 | 2 |
| Component (D) | HAT | 0.14 | — | 0.14 | 0.20 | — | — |
| (mmol/g) | TA-LX | — | 0.14 | — | — | — | — |
| Component | BT- | — | — | — | — | 0.14 | — |
| (D′) (mmol/g) | 120SG | | | | | | |
| | BT-LX | — | — | — | — | — | 0.14 |
| Component (E) | KBM-503 | 1.7 | 1.7 | 5.1 | 5.1 | 1.7 | 1.7 |
| Component (F) | TEMPOL | 0.25 | 0.25 | 0.25 | 0.25 | 0.25 | 0.25 |
| Discoloration | R | 246 | 250 | 198 | 207 | 182 | 144 |
| resistance | G | 175 | 128 | 144 | 148 | 92 | 61 |
| | B | 134 | 121 | 110 | 112 | 168 | 147 |
| | d | 34 | 74 | 71 | 64 | 105 | 151 |

1. A photosensitive resin composition comprising:
a maleimide compound;
a crosslinking agent;
a photopolymerization initiator; and
a rust inhibitor, wherein
the maleimide compound is a reaction product of a tetracarboxylic dianhydride (a1), an amine (a2), and a maleic anhydride (a3), and
the rust inhibitor contains a compound represented by Formula (I) described below: 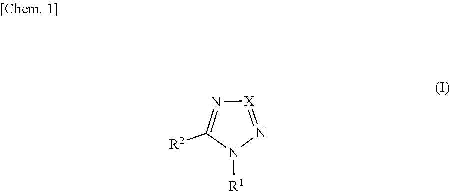
Wherein in Formula (I), X represents a carbon atom or a nitrogen atom, and R¹ and R² each independently represent a hydrogen atom, an alkyl group, an aryl group, or a nitrogen-containing group, where in a case where X represents a nitrogen atom, R¹ and R² do not both represent a hydrogen atom.

2. The photosensitive resin composition according to claim 1, wherein the amine (a2) contains a dimer diamine and a second amine other than the dimer diamine.

3. The photosensitive resin composition according to claim 1, wherein at least one of the tetracarboxylic dianhydride (a1) and the amine (a2) contains a compound having a fluorene skeleton.

4. The photosensitive resin composition according to claim 1, wherein the tetracarboxylic dianhydride (a1) includes at least one of 1,3,3a,4,5,9b-hexahydro-5(tetrahydro-2,5-dioxo-3-furanyl)naphtho[1,2-C]furan-1,3-dione, 9,9-bis(3,4-dicarboxyphenyl)fluorene dianhydride, and 9,9-bis[4-(3,4-dicarboxyphenoxy)phenyl]fluorene dianhydride.

5. The photosensitive resin composition according to claim 2, wherein the second amine contains at least one of norbornanediamine and 9,9-bis[4-(4-aminophenoxy)phenyl]fluorene.

6. A cured product of the photosensitive resin composition according to claim 1.

7. A semiconductor element comprising a redistribution layer containing a cured product of the photosensitive resin composition according to claim 1.
